(19) United States
(12) Patent Application Publication
(10) Pub. No.: US 2025/0169263 A1
(43) Pub. Date: May 22, 2025

(54) Micro LED Display Device and Method for Manufacturing Micro LED Display Device

(71) Applicant: KOREA INSTITUTE OF ENERGY TECHNOLOGY, Naju-si (KR)

(72) Inventors: Joon Seop Kwak, Suncheon-si (KR); Tae Kyoung Kim, Suncheon-si (KR)

(21) Appl. No.: 18/840,093

(22) PCT Filed: Feb. 22, 2023
(86) PCT No.: PCT/KR2023/002529

§ 371 Date: Aug. 21, 2024

(30) Foreign Application Priority Data
Feb. 22, 2022 (KR) 10-2022-0022907

(51) Int. Cl. H10H 29/80; H10H 29/01

(52) U.S. Cl. CPC H10H 29/8321; H10H 29/012

(57) ABSTRACT

The present relates to a micro LED display device and a method for manufacturing the micro LED display device, wherein micro LEDs and a drive substrate can be stably bonded without a reduction in light extraction efficiency. The micro LED display device a drive substrate having a first pad and a second pad that are connected to different potentials; and micro LEDs having a light-emitting structure in which an n-type semiconductor layer, an active layer, and a p-type semiconductor layer are stacked, an n-type pad electrically connecting the n-type semiconductor layer and the first pad, and a p-type pad electrically connecting the p-type semiconductor layer and the second pad. One of the n-type pad or the p-type pad may be provided on a side surface of the light-emitting substrate.

### CROSS-REFERENCE TO RELATED APPLICATIONS

This application is the United States national phase of International Patent Application No. PCT/KR2023/002529 filed Feb. 22, 2023, and claims priority to Korean Patent Application No. 10-2022-0022907 filed Feb. 22, 2022, the disclosures of which are hereby incorporated by reference in their entireties.

### BACKGROUND

### Technical Field

The present disclosure relates to a micro light emitting diode (LED) display device and a method for manufacturing a micro LED display device, and more particularly, to a micro LED display device and a method for manufacturing a micro LED display device that enable stable bonding of a micro LED and a driving substrate without reducing light extraction efficiency.

### Technical Considerations

Semiconductor LEDs have been widely used not only as light sources for lighting devices but also as light sources for various display devices of various electronic products, such as TVs, mobile phones, personal computers (PCS), laptops, personal digital assistants (PDAs), etc. In particular, micro LEDs in which a length of one side is 100 μm or less have been developed recently. Micro LEDs have a fast response speed, consume less power, and high brightness compared to existing LEDs and have thus come to prominence as light-emitting devices for next-generation displays.

In manufacturing a display using micro LEDs, a flip-chip type micro LED element in which an n bonding pad and a p bonding pad are formed horizontally not only is advantageous for miniaturization, weight reduction, and high integration of a single element, but also improves light-emitting efficiency and efficiency of a transfer process in manufacturing a display device, and is therefore mainly used in the micro LED field.

Meanwhile, as the resolution of display devices increases and the size of the pixels of display devices decreases, the micro LEDs that make up pixels or sub pixels also decrease in size and it is necessary to bond the micro LEDs that gradually decrease in size to an accurate position of a driving substrate (or a backplane).

In the case of using a general flip-chip type micro LED, an active region (MQWs) has to be removed to form an n contact, but the reduction in the active region may cause a problem of reduced light extraction efficiency. In addition, since the n bonding pad and the p bonding pad exist horizontally, a distance between the n bonding pad and the p bonding pad is very narrow during flip-chip bonding with the driving substrate or backplane, so there is a high possibility that an electrical short may occur due to a bonding material, and even if the problem of short-circuit occurrence is solved, there is still another problem of misalignment with the driving substrate.
(Patent Document 1) Korean Application Publication No. 10-2018-0009116

### SUMMARY

An object of the present disclosure is to provide a micro LED display device and a method for manufacturing a micro LED display device that enable stable bonding between a micro LED and a driving substrate without decreasing light extraction efficiency.

In one general and non-limiting aspect, a micro LED display device includes: a driving substrate including a first pad and a second pad connected to different potentials; and a micro LED including a light-emitting structure in which an n-type semiconductor layer, an active layer, and a p-type semiconductor layer are stacked, an n-type pad electrically connecting the n-type semiconductor layer to the first pad, and a p-type pad electrically connecting the p-type semiconductor layer to the second pad, wherein one of the n-type pad and p-type pad is provided on a side surface of the light-emitting structure.

The other of the n-type pad and p-type pad may be provided on a front or rear surface of the light-emitting structure.

One of the n-type pad and the p-type pad provided on the side surface of the light-emitting structure may be provided at a higher position than the other of the n-type pad and the p-type pad provided on the front or rear surface of the light-emitting structure.

The driving substrate may further include a side contact portion extending from the first pad or the second pad electrically connected to one of the n-type pad and the p-type pad provided on the side surface of the light-emitting structure toward one of the n-type pad and the p-type pad provided on the side surface of the light-emitting structure.

The driving substrate may further include: a plurality of driving thin film transistors (TFTs) individually driving ON/OFF of the micro LEDs provided in plurality; and a common voltage interconnection providing a common potential to the plurality of micro LEDs, wherein one of the first pad and the second pad is electrically connected to a source/drain electrode of the driving TFT, and the other of the first pad and the second pad is electrically connected to the common voltage interconnection.

The micro LED may further include a passivation layer provided on side surfaces of the active layer and the p-type semiconductor layer.

When the p-type pad is provided on the side surface of the light-emitting structure, the micro LED may further include a transparent p-type electrode provided on the p-type semiconductor layer.

One of the n-type pad and the p-type pad provided on the side surface of the light-emitting structure and a side contact portion may each include a material for forming a eutectic mixture during a bonding process.

The driving substrate may further include an insulating layer having a through-hole provided to expose the first pad and the second pad, and a cross-sectional area of the through-hole corresponding to the first pad or the second pad electrically connected to the n-type pad or the p-type pad provided on the front or rear surface of the light-emitting structure may be larger than a cross-sectional area of the light-emitting structure.

An effective cross-sectional area of the micro LED may be 100 μm² or less.

In another general and non-limiting aspect, a method for manufacturing a micro LED display device includes: an operation of preparing a driving substrate including a first pad and a second pad connected to different potentials; an operation of preparing a plurality of micro LEDs including a light-emitting structure in which an n-type semiconductor layer, an active layer, and a p-type semiconductor layer are stacked, an n-type pad electrically connected to the n-type semiconductor layer, and a p-type pad electrically connected to the p-type semiconductor layer, one of the n-type pad and the p-type pad being provided on a side surface of the light-emitting structure; and an operation of bonding the plurality of micro LEDs to the driving substrate so that one of the n-type pad and the p-type pad provided on the side surface of the light-emitting structure is electrically connected to one of the first pad and the second pad and the other of the n-type pad and the p-type pad is electrically connected to the other of the first pad and the second pad.

The operation of preparing the driving substrate may include an operation of forming a side contact portion extending from the first pad or the second pad electrically connected to one of the n-type pad and the p-type pad provided on the side surface of the light-emitting structure toward one of the n-type pad and the p-type pad provided on the side surface of the light-emitting structure.

The operation of bonding the plurality of micro LEDs to the driving substrate may include an operation of supplying energy so that one of the n-type pad and the p-type pad provided on the side surface of the light-emitting structure and the side contact portion form a eutectic mixture.

The driving substrate may further include an insulating layer having a through-hole provided to expose the first pad and the second pad, and the operation of bonding the plurality of micro LEDs to the driving substrate may include an operation of inserting at least a portion of the micro LED into the through-hole corresponding to the first pad or the second pad electrically connected to the n-type pad or the p-type pad provided on a front or rear surface of the light-emitting structure.

The micro LED may further include a passivation layer provided on side surfaces of the active layer and the p-type semiconductor layer.

According to the micro LED display device and the method for manufacturing a micro LED display device according to an exemplary and non-limiting embodiment of the present disclosure, since one of the n-type pad and the p-type pad is provided on the side surface of the light-emitting structure, there is no need to remove the active region to form the n-type pad in the flip-chip type micro LED, and thus, a decrease in the light-emitting efficiency due to the decrease in the active region may be suppressed.

In addition, since the n-type pad and the p-type pad are provided at different heights so as not to exist on the same horizontal plane and are electrically connected using the side contact portion, the occurrence of an electrical short due to contacting of bonding materials when bonding the micro LED and the driving substrate (or the backplane) may be effectively prevented.

In addition, stable bonding may be performed simply by forming a eutectic mixture between the n-type pad or the p-type pad and the side contact portion by supplying energy while the n-type pad or the p-type pad is in contact with the side contact portion.

Meanwhile, by inserting at least a portion of the micro LED into the through-hole of the insulating layer provided to expose the first pad and the second pad and bonding the same, the micro LED and the driving substrate may be precisely aligned, and a bonding material is prevented from spreading by the through-hole, thereby enabling stable bonding.

### BRIEF DESCRIPTION OF THE DRAWINGS

FIG. 1 is a cross-sectional view of a micro LED display device according to an exemplary and non-limiting embodiment of the present disclosure;

FIG. 2 is a cross-sectional view of a micro LED display device according to another exemplary and non-limiting embodiment of the present disclosure;

FIG. 3 is a flowchart of a method for manufacturing a micro LED display device according to another exemplary and non-limiting embodiment of the present disclosure;

FIG. 4 is a view illustrating a sequential operation of a method for manufacturing a micro LED display device according to another exemplary and non-limiting embodiment of the present disclosure; and

FIG. 5 is a view illustrating a sequential operation of a method for manufacturing a micro LED display device according to another exemplary and non-limiting embodiment of the present disclosure.

### DETAILED DESCRIPTION

Hereinafter, specific exemplary and non-limiting embodiments will be explained in more detail with reference to the accompanying drawings. This disclosure may, however, be embodied in different forms and should not be construed as limited to the exemplary embodiments set forth herein. Rather, these exemplary embodiments are provided so that this disclosure will be thorough and complete, and will fully convey the scope of the disclosure to those skilled in the art. Like reference symbols in the various drawings indicate like elements. In addition, in the drawings, the sizes of layers and regions are exaggerated for clarity of illustration.

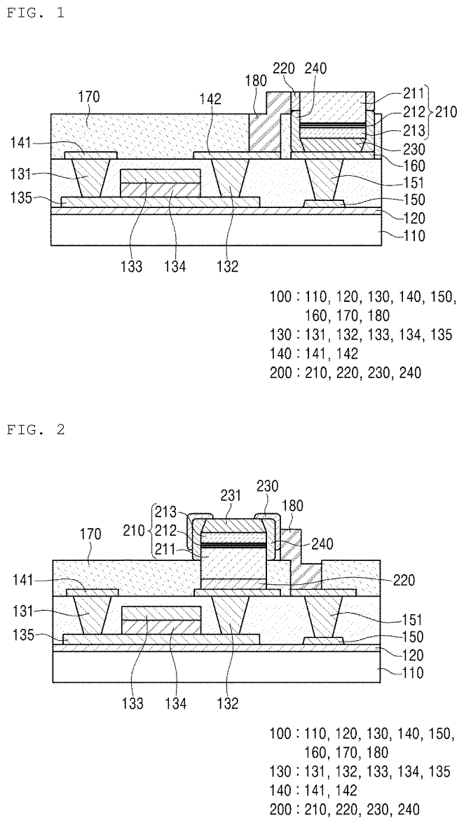

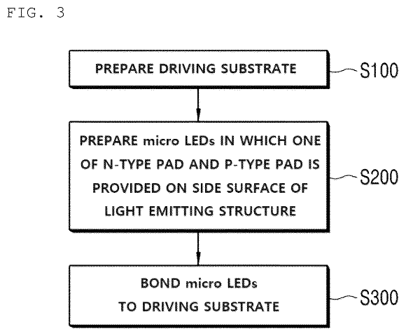

FIG. 1 is a cross-sectional view of a micro LED display device (n-type side pad type) according to an exemplary and non-limiting embodiment of the present disclosure, and FIG. 2 is a cross-sectional view of a micro LED display device (p-type side pad type) according to another exemplary and non-limiting embodiment of the present disclosure.

Referring to FIGS. 1 and 2, a micro LED display device according to an exemplary and non-limiting embodiment of the present disclosure includes a driving substrate 100 having a first pad 142 and a second pad 160 connected to different potentials; and a micro LED 200 including a light-emitting structure 210 in which an n-type semiconductor layer 211, an active layer 212, and a p-type semiconductor layer 213 are stacked, an n-type pad 220 electrically connecting the n-type semiconductor layer 211 to the first pad 142, and a p-type pad 230 electrically connecting the p-type semiconductor layer 213 to the second pad 160. Here, one of the n-type pad 220 and the p-type pad 230 may be provided on a side surface of the light-emitting structure 210, and the other of the n-type pad 220 and the p-type pad 230 may be provided on a front or rear surface of the light-emitting structure 210.

The micro LED display device is a display device having an array structure in which a plurality of micro LED pixels bonded on the driving substrate 100 including circuits for driving the micro LED or sub-pixels constituting one unit pixel for color display are arranged in a two-dimensional matrix form and may perform a function of outputting R/G/B light corresponding to an image signal of the display device. Here, the plurality of micro LED pixels may include any one of a blue light-emitting element, a green light-emitting element, a red light-emitting element, and a UV light-emitting element, but without being limited thereto, and the arrangement of pixels or sub-pixels of the micro LED display device formed thereby may also have various forms.

The driving substrate 100 may include a base substrate 110 that supports a thin film transistor (TFT), an integrated circuit element, or a metal interconnection for driving the micro LED, while providing structural strength. The base substrate 110 may be formed of a ceramic material, such as gallium nitride, glass, sapphire, quartz, or silicon carbide, or an organic material, such as polyethylene terephthalate, polyethylene naphthalate, polycarbonate, polyethersulfone, polycyclic olefin, or polyimide.

A buffer layer 120 formed of an electrically insulating material, such as SiO₂ may be provided on the base substrate 110. The buffer layer 120 may provide a flat surface in an upper portion of the base substrate 110 and may block foreign substances or moisture from penetrating through the base substrate 110.

On the buffer layer 120, there may be further provided a plurality of driving TFTs 130 to individually drive ON/OFF of the micro LED 200 provided in plurality to form pixels or sub-pixels and a common voltage interconnection 150 that provides a common potential to the plurality of micro LEDs 200.

The driving TFT 130 may include a gate electrode 133, a gate oxide 134, a source electrode 131, a drain electrode 132, and a semiconductor layer 135 formed of a semiconductor material, such as oxide semiconductor, LTPS, LTPO, amorphous silicon, AlGaN/GaN, etc. The semiconductor layer 135 includes an active region forming a channel in the central portion and a source region and a drain region doped with a high concentration of impurities provided on both sides of the active region.

On the driving TFT 130, an interlayer insulating film that not only flattens a step caused by the driving TFT 130 structure but also electrically insulates may be formed.

The common voltage interconnection 150 may be provided for each of a plurality of unit pixels. In this case, at least three R/G/B subpixels constituting each unit pixel share one common voltage interconnection 150. Accordingly, the number of common voltage interconnections 150 for driving each subpixel may be reduced, and an aperture ratio of each unit pixel may be increased or a size of each unit pixel may be reduced by the reduced number of common voltage interconnections 150.

The driving substrate 100 may include the first pad 142 and second pad 160 connected to different potentials. A low potential voltage (e.g., ground or Vₛₛ) may be applied to the first pad 142 electrically connected to the n-type semiconductor layer 211 of the micro LED and a high potential voltage V_{dd} may be applied to the second pad 160 electrically connected to the p-type semiconductor layer 213 of the micro LED to cause the micro LED 200 to emit light.

Meanwhile, one of the first pad 142 and the second pad 160 may be electrically connected to the source/drain electrode 131 and 132 of the driving TFT 130, and the other of the first pad 142 and the second pad 160 may be electrically connected to the common voltage interconnection 150 through a common interconnection electrode 151.

The micro LED 200, which is a light-emitting unit constituting the pixel or subpixel of the micro LED display device, may be disposed on the driving substrate 100. The micro LED 200 may emit light having a wavelength of ultraviolet, red, green or blue and may realize white light or light of various colors by converting emitted light into a phosphor material or combining colors.

The micro LED 200 may include the light-emitting structure 210 in which the n-type semiconductor layer 211, the active layer 212, and the p-type semiconductor layer 213 are sequentially stacked, the n-type pad 220 electrically connecting the n-type semiconductor layer 211 to first pads 141 and 142, and the p-type pad 230 electrically connecting the p-type semiconductor layer 213 to the second pad 160.

The n-type semiconductor layer 211 may be selected from, for example, compound semiconductor materials having a composition formula of InₓAl_{y}Ga_{1-x-y}N (0≤x≤1, 0≤y≤1), such as GaN, AlN, AlGaN, InGaN, InN, InAlGaN, AlInN, etc., and may be doped with an n-type dopant, such as Si, Ge, or Sn.

The active layer 212 is a region in which electrons and holes are recombined, and as the electrons and holes are recombined, they transition to a lower energy level and may generate light having a corresponding wavelength. The active layer 213 may be formed to include, for example, a compound semiconductor material having a composition formula of InₓAl_{y}Ga_{1-x-y}N (0≤x≤1, 0≤y≤1) and may be formed as a single quantum well structure or a multi-quantum well structure (MQW). In addition, the active layer 212 may include a quantum wire structure or a quantum dot structure.

The p-type semiconductor layer 213 may be selected from, for example, a compound semiconductor material having a composition formula of InₓAl_{y}Ga_{1-x-y}N (0≤x≤1, 0≤y≤1), i.e., GaN, AlN, AlGaN, InGaN, InN, InAlGaN, AlInN, etc., and may be doped with a p-type dopant, such as Mg, Zn, Ca, Sr, or Ba.

The micro LED used in the micro LED display device of the related art is a flip-type micro LED in which the n-type pad and the p-type pad are horizontally arranged on the same plane. When a general flip-chip type micro LED is used, the active region (MQWs) has to be removed to form an n contact, but a problem of reduced light extraction efficiency may occur due to a reduction of the active region. In addition, since the n-type pad and the p-type pad exist horizontally, the distance between the n-type pad and the p-type pad is very narrow during flip-chip bonding with the driving substrate or backplane, so there is a very high possibility that an electrical short may occur due to a bonding material. These characteristics of the flip-type micro LED could become more serious as the resolution of micro LED display device increases and the micro LEDs that make up pixels or sub-pixels are reduced in size.

In general, a length of one side of micro LEDs may be 100 μm or less, but in ultra-high-resolution display devices recently on demand in which an ultra-small micro LEDs having an effective cross-sectional area of the micro LED (or an effective cross-sectional area of the n-type semiconductor layer) of 100 μm² or less is required, if a portion of the active layer is removed to form an n-type pad, the light-emitting region may become too small, making it difficult to secure sufficient light. In order for pixels or sub-pixels forming a two-dimensional array to exhibit uniform light-emitting characteristics without being affected by direction, it is desirable for the pixel or subpixel to have a square cross-sectional shape. However, in the case of square-shaped ultra-small micro LEDs, the length of one side is merely 10 μm or less, so the distance between the n-type pad and the p-type pad is very narrow and there is a high possibility that an electrical short will occur due to a bonding material.

In order to solve the problem of the flip chip-type micro LED, in the present disclosure, one of the n-type pad 220 and the p-type pad 230 is provided on the side surface of the light-emitting structure 210 and the other of the n-type pad 220 and the p-type pad 230 may be provided on the front or rear surface of the light-emitting structure. That is, the relative positions of the n-type pad 220 and the p-type pad 230 may not form a horizontal structure or a vertical structure, but form a structure in which the extending surface of the n-type pad 220 and the extending surface of the p-type pad 230 intersect each other in the present disclosure. For example, the n-type pad 220 and the p-type pad 230 form a right-angled structure.

Since one of the n-type pad 220 and the p-type pad 230 is provided on the side surface of the light-emitting structure 210 to form a side contact, it may be unnecessary to remove a portion of the active layer to form the n-type pad in the flip-chip type micro LED of the related art and the entire planar area of the micro LED (the planar area of the active layer and the planar area of the micro LED are substantially the same) is used for light emission, thereby securing sufficient light.

In addition, one of the n-type pad 220 and the p-type pad 230 provided on the side surface of the light-emitting structure 210 may be provided at a higher position than the other of the n-type pad 220 and the p-type pad 230 provided on the front or rear surface of the light-emitting structure 210. Since the n-type pad 220 and the p-type pad 230 are provided at different heights, even when heat is applied, while pressing the micro LED against the driving substrate during the operation of bonding the micro LED to the driving substrate, an electrical short due to a spreading phenomenon of the bonding material may be effectively suppressed.

Meanwhile, the micro LED 200 may be in the form of a single chip separated by dicing a plurality of light-emitting units or light-emitting elements formed on a growth substrate, such as sapphire. The growth substrate may be removed by lifting off a sacrificial layer interposed between the growth substrate and the plurality of light-emitting units with a laser. Alternatively, the plurality of light-emitting units formed on the growth substrate may be transferred onto a submount and then separated into a single chip by dicing.

In the single-chip type micro LED 200, since the n-type pad 220 and the p-type pad 230 are provided at different heights, a new bonding mechanism different from the general flip-chip bonding is required to connect them to the first pad 142 and the second pad 160 located at the same level on the driving substrate 100.

To this end, the driving substrate 100 may further include a side contact portion 180 extending from the first pad 142 or the second pad 160 electrically connected to one of the n-type pad and the p-type pad 220 and 230 provided on the side surface of the light-emitting structure 210 toward one of the n-type pad and the p-type pad 220 and 230 provided on the side surface of the light-emitting structure 210. That is, in order to connect the first pad 142 and the second pad 160 located at the same level to the n-type pad 220 and the p-type pad 230 provided at different heights, a component that fills the height difference between the pads is required, and electrical connection may be made by using the side contact portion 180 that extends upward from the first pad or the second pad corresponding to one of the n-type pad 220 and the p-type pad 230 provided on the side surface of the light-emitting structure 210.

Meanwhile, the side contact portion 180 may extend upward from the first pad 142 and the second pad 160, may be a pillar shape that protrudes further than an insulating layer 170 including a through-hole 171 provided to expose the first pad 142 and the second pad 160, or may be in a form embedded in the insulating layer 170.

In the n-type side pad type micro LED display device illustrated in FIG. 1, the p-type semiconductor layer 213 faces downward, and the p-type pad 230 formed on the p-type semiconductor layer 213 (i.e., the front surface of the light-emitting structure) is electrically connected to the second pad 160. The electrical connection may be formed by interposing a bonding material, such as a solder ball, between the p-type pad 230 and the second pad 160 or the electrical connection may be formed by forming a eutectic mixture between the p-type pad 230 and the second pad 160.

In addition, the p-type pad 230 may function as a p-type electrode, or a p-type electrode may be additionally inserted to form a better ohmic contact between the p-type pad 230 and the p-type semiconductor layer 213. The p-type pad 230 or p-type electrode may provide a reflective surface to reflect light incident upon being emitted from the active layer 212 upward.

The n-type pad 220 formed on the side surface of the light-emitting structure 210 may be provided on a side surface of the n-type semiconductor layer 211. The n-type semiconductor layer 211 may be doped with a high concentration of n-type impurities to have high electrical conductivity. Therefore, even if the n-type pad 220 is provided on the side surface of the n-type semiconductor layer 211, voltage may be uniformly formed throughout the n-type semiconductor layer, so that light may be uniformly emitted from the active layer 212. The n-type pad 220 may form a reflective surface so that light emitted from the active layer 212 may not be spread sideways but be emitted through an upper surface.

An n-type electrode may be further interposed between the n-type pad 220 and the n-type semiconductor layer 211 to form an ohmic contact. Here, the n-type electrode may be formed as a single layer formed of Cr, Ni, Ti, etc. for ohmic contact with the n-type semiconductor layer or may be formed as a double layer including a first electrode layer for ohmic contact with the n-type semiconductor layer and a second electrode layer formed of Au, Al, Ag, Pt, Pd, etc. having excellent electrical conductivity stacked on the first electrode layer.

The side contact portion 180 may extend upward from the first pad 142 and be electrically connected to the n-type pad 220 provided at a higher position than the p-type pad 230. When the single-chip type micro LED 200 is mounted on the driving substrate 100, the side contact portion 180 may come into contact with the n-type pad 220 provided on the side surface of the light-emitting structure 210 and a eutectic mixture may be formed as a reactant between the side contact portion 180 and the n-type pad 220 by energy (thermal energy or light energy, etc.) supplied during the bonding process and electrically connected.

The side contact portion 180 and the n-type pad 220 may each include a material that forms the eutectic mixture during the bonding process. That is, at least one metal among materials forming the side contact portion 180 and at least one metal forming the n-type pad 220 may form the eutectic mixture. The materials forming the eutectic mixture may be included in both the side contact portion 180 and the n-type pad 220.

The side contact portion 180 and the n-type pad 220 may include at least one of Pb, Sn, Au, Ge, Si, In, Ag, and Cu materials. In order to easily form the eutectic mixture by energy supplied during the bonding process, at least one of the side contact portion 180 and the n-type pad 220 may include tin (Sn), and the other of the side contact portion 180 and the n-type pad 220 may include a metal that forms a eutectic mixture with tin.

In the p-type side pad type micro LED display device illustrated in FIG. 2, the n-type semiconductor layer 211 faces downward, and the n-type pad 220 formed on the n-type semiconductor layer 211 (i.e., the rear surface of the light-emitting structure) is electrically connected to the first pad 142. The electrical connection may be formed by interposing a bonding material, such as a solder ball, between the n-type pad 220 and the first pad 142, or the electrical connection may be formed by forming a eutectic mixture between the n-type pad 220 and the first pad 142.

In addition, the n-type pad 220 may function as an n-type electrode, or an n-type electrode may be additionally inserted to form a better ohmic contact between the n-type pad 220 and the n-type semiconductor layer 211. The n-type pad 220 or n-type electrode may provide a reflective surface to reflect light incident upon being emitted from the active layer 212 upward.

The p-type pad 230 formed on the side surface of the light-emitting structure 210 may be provided on a side surface of the p-type semiconductor layer 213. The p-type pad 230 may be formed of a metal having excellent reflective properties, such as Ni or Ag, to form a reflective surface so that light emitted from the active layer 212 may not be spread sideways but be emitted through the upper surface.

The micro LED 200 may further include a transparent p-type electrode 231 provided on the p-type semiconductor layer 213. The transparent p-type electrode 231 may include at least one of conductive oxides, such as indium tin oxide (ITO), indium zinc oxide (IZO), zinc oxide (ZnO), indium oxide (In₂O₃), indium gallium oxide (IGO), and aluminum zinc oxide (AZO).

The p-type semiconductor layer 213 is doped with a lower concentration of impurities than the n-type semiconductor layer 211 and is inevitably thinner than the n-type semiconductor layer 211, so that the electrical conductivity is low. As a result, applied voltage is uniformly formed over the entire p-type semiconductor layer 213 to form the transparent p-type electrode 231 on the p-type semiconductor layer 231 so that light may be uniformly emitted from the active layer 212. In order to prevent the p-type pad 230 formed on the side surface of the light-emitting structure 210 from interfering with the upward light emission of the upper surface of the p-type semiconductor layer 213, the p-type pad 230 may be electrically connected to the transparent p-type electrode 231 at an edge of the transparent p-type electrode 231.

The side contact portion 180 may extend upward from the second pad 160 to be electrically connected to the p-type pad 230 provided at a higher position than the n-type pad 220. When the single-chip type micro LED 200 is mounted on the driving substrate 100, the side contact portion 180 may come into contact with the p-type pad 230 provided on the side surface of the light-emitting structure 210 and a eutectic mixture may be formed as a reactant between the side contact portion 180 and the p-type pad 230 by energy (such as thermal energy or light energy) supplied during the bonding process and electrically connected.

The side contact portion 180 and the p-type pad 230 may each include a material that forms the eutectic mixture during the bonding process. That is, at least one metal among the materials forming the side contact portion 180 and at least one metal forming the p-type pad 230 may form the eutectic mixture. The materials forming the eutectic mixture may be included in both the side contact portion 180 and the p-type pad 230.

The side contact portion 180 and the p-type pad 230 may include at least one of Pb, Sn, Au, Ge, Si, In, Ag, and Cu materials. In order to easily form the eutectic mixture by the energy supplied during the bonding process, at least one of the side contact portion 180 and the p-type pad 230 may include tin (Sn), and the other of the side contact portion 180 and the p-type pad 230 may include a metal forming the eutectic mixture with tin.

The n-type pad 220 or the p-type pad 230 formed on the side surface of the light-emitting structure 210 may be misaligned, or during the operation of bonding the micro LED 200 and the driving substrate 100, a partial region may be locally melted so that a conductive material forming the n-type pad 220 or the p-type pad 230 may be applied to the side surface of the active layer 212 to cause a short-circuit between the n-type semiconductor layer 211 and the p-type semiconductor layer 213. If the n-type semiconductor layer 211 and the p-type semiconductor layer 213 are short-circuited, light may not be emitted from the active layer 212. Therefore, in order to solve this problem, the micro LED 200 of the present disclosure may further include an electrically insulating passivation layer 240 provided on side surfaces of the active layer 212 and the p-type semiconductor layer 213. The passivation layer 240 may also be provided on an upper side surface (active layer side) of the n-type semiconductor layer 211 in order to more stably insulate the n-type semiconductor layer 211 and the p-type semiconductor layer 213 from each other.

Meanwhile, the driving substrate 100 according to the exemplary and non-limiting embodiment of the present disclosure may further include the insulating layer 170 having the through-hole 171 provided to expose the first pad 142 and the second pad 160. Here, a cross-sectional area of the through-hole corresponding to the first pad 142 or the second pad 160 electrically connected to the n-type pad 220 or the p-type pad 230 provided on the front or rear surface of the light-emitting structure 210 may be larger than a cross-sectional area of the light-emitting structure 210. That is, since at least a portion of the micro LED 200 may be inserted and bonded into the through-hole corresponding to the first pad 142 or the second pad 160 electrically connected to the n-type pad 220 or the p-type pad 230 provided on the front or rear surface of the light-emitting structure 210, the through-hole may act as an accommodation space accommodating at least a portion of the micro LED 200.

The single chip-type micro LED 200 may be picked up individually or collectively by a transfer mechanism, transferred to the driving substrate 100, and then bonded to the driving substrate 100 to be mounted on the driving substrate 100. In the operation of bonding the micro LED 200 transferred on the driving substrate 100 to the driving substrate 100, energy, such as heat and pressure, may be applied to the micro LED 200.

Meanwhile, in order for the micro LED 200 to be accurately mounted on the driving substrate 100, the micro LED 200 has to be precisely located at a mounting position on the driving substrate 100, and even after the micro LED 200 is located so that the n-type pad and/or the p-type pad 220 and 230 correspond to the first pad 142 and/or the second pad 160 during the transfer process, the micro LED 200 should not be shifted from the transferred position by thermal compression of the bonding process.

When the micro LED 200 is transferred to the driving substrate 100, the through-hole corresponding to the first pad 142 or the second pad 160 electrically connected to the n-type pad 220 or the p-type pad 230 provided on the front or rear surface of the light-emitting structure 210 may be used as a position determining unit of the micro LED to transfer the micro LED to the accurate position. In addition, by inserting and bonding at least a portion of the micro LED 200 into the through-hole, the micro LED 200 may be prevented from shifting away from the transferred position by thermal compression during the bonding process. Furthermore, when bonding the micro LED 200 and the driving substrate 100, at least a locally melted bonding material, etc. may be accommodated in a space between an inner wall of a driving hole and the side surface of the light-emitting structure 210, so that a spreading phenomenon of the bonding material may be suppressed, thereby preventing the n-type pad and the p-type pad from being electrically short-circuited.

In the micro LED display device according to an exemplary and non-limiting embodiment of the present disclosure, an effective cross-sectional area of the micro LED 200 (or an effective cross-sectional area of the n-type semiconductor layer) may be an ultra-small micro LED of 100 μm or less. By providing the n-type pad 220 or the p-type pad 230 on the side surface of the light-emitting structure 210, the n-type semiconductor layer 211, the active layer 212, and the p-type semiconductor layer 213 constituting the light-emitting structure 210 may have the same cross-sectional area without the need to remove a portion of the active layer to form an n-type pad in the existing flip-chip type micro LED, so that the entire cross-section of the light-emitting structure 210 may be used as a light-emitting region to secure sufficient light.

Also, the cross-section of the light-emitting structure 210 may be square so that the pixels or sub-pixels of the micro LED 200 arranged in a two-dimensional array may not be affected by the direction and exhibit uniform light-emitting characteristics.

In addition, in the present disclosure, an extension surface of the n-type pad 220 and an extension surface of the p-type pad 230 intersect each other. For example, the n-type pad 220 and the p-type pad 230 form a right-angled structure. Through this, the n-type pad 220 and the p-type pad 230 may be provided at different heights, so that even when heat is applied, while pressing the micro LED against the driving substrate, during the operation of bonding the micro LED to the driving substrate, an electrical short-circuit caused by a spreading phenomenon of a bonding material may be effectively suppressed.

The effective cross-sectional area of the micro LED 200 (or the effective cross-sectional area of the n-type semiconductor layer) may effectively improve the resolution of the micro LED display device including an ultra-small micro LED of 100 μm² or less than the case of using the general flip-chip type micro LED.

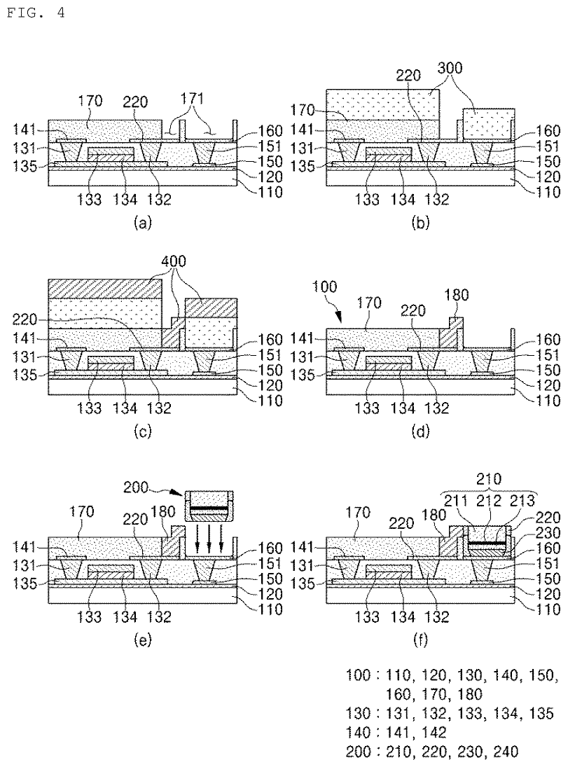

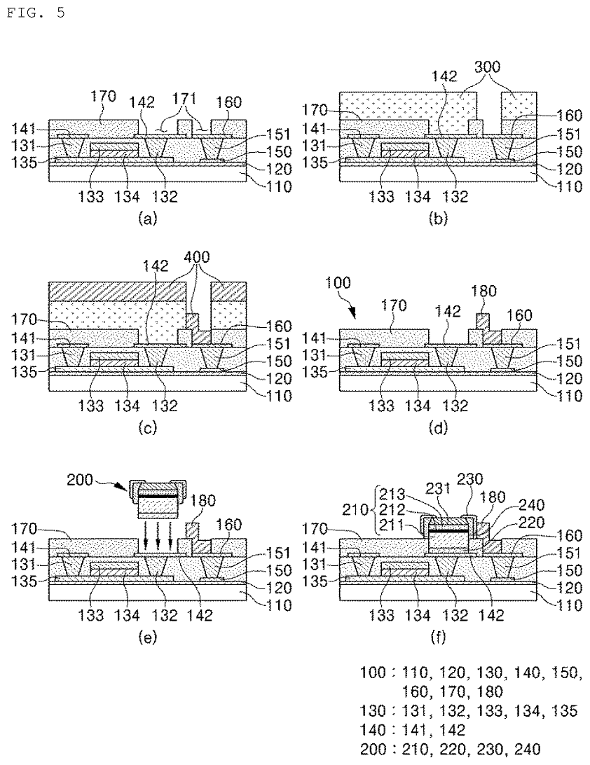

FIG. 3 is a flowchart of a method for manufacturing a micro LED display device according to another exemplary and non-limiting embodiment of the present disclosure, FIG. 4 is a view illustrating a sequential operation of a method for manufacturing a micro LED display device (an n-type side pad type) according to another exemplary embodiment of the present disclosure, and FIG. 5 is a view illustrating a sequential operation of a method for manufacturing a micro LED display device (a p-type side pad type) according to another exemplary embodiment of the present disclosure

In describing the method for manufacturing a micro LED display device according to another exemplary and non-limiting embodiment of the present disclosure, any details which are the same as those described above in relation to the micro LED display device according to the exemplary and non-limiting embodiment of the present disclosure will be omitted.

Referring to FIGS. 3 to 5, the method for manufacturing a micro LED display device according to another exemplary and non-limiting embodiment of the present disclosure may include a process (S100) of preparing a driving substrate 100 having the first pad 142 and the second pad 160 connected to different potentials; a process (S200) of preparing a plurality of micro LEDs 200 including the light-emitting structure 210 in which the n-type semiconductor layer 211, the active layer 212, and the p-type semiconductor layer 213 are stacked, the n-type pad 220 electrically connected to the n-type semiconductor layer 211, and the p-type pad 230 electrically connected to the p-type semiconductor layer 213, wherein one of the n-type pad 220 and the p-type pad 230 is provided on a side surface of the light-emitting structure 210; and a process (S300) of bonding the plurality of micro LEDs 200 to the driving substrate 100 so that one of the n-type pad 220 and the p-type pad 230 provided on the side surface of the light-emitting structure 210 is electrically connected to one of the first pad 142 to the second pad 160 and the other of the n-type pad and the p-type pad is electrically connected to the other of the first pad 142 to the second pad 160.

Each operation of the method for manufacturing a micro LED display device according to another exemplary and non-limiting embodiment of the present disclosure may not be performed in chronological order, and each process may be performed in the reverse order or may be performed simultaneously, if necessary. For example, the process (S100) of preparing the driving substrate 100 and the process (S200) of preparing the plurality of micro LEDs 200 may be performed in the reverse order or simultaneously.

First, the driving substrate 100 including the first pad 142 and the second pad 160 connected to different potentials may be prepared (see S100).

The driving substrate 100 may include the base substrate 110 that supports a thin film transistor (TFT), an integrated circuit element, or a metal interconnection for driving the micro LED, while providing structural strength.

The buffer layer 120 formed of an electrically insulating material, such as SiO₂, may be provided on the base substrate 110.

On the buffer layer 120, a plurality of driving TFTs 130 individually driving ON/OFF of the micro LEDs 200 provided in plurality to configure pixels or subpixels and the common voltage interconnection 150 providing a common potential to the micro LEDs 200 provided in plurality may be further included. Here, the driving TFT 130 may include the gate electrode 133, the gate oxide 134, the source electrode 131, the drain electrode 132, and the semiconductor layer 135.

An interlayer insulating film may be formed on the driving TFT 130 to not only flatten a step caused by the structure of the driving TFT 130 but also electrically insulate the step.

The driving substrate 100 may include the first pad 142 and the second pad 160 connected to different potentials. A low potential voltage (for example, ground or Vₛₛ) may be applied to the first pad 142 electrically connected to the n-type semiconductor layer 211 of the micro LED and a high potential voltage V_{dd} may be applied to the second pad 160 electrically connected to the p-type semiconductor layer 213 of the micro LED, thereby causing the micro LED 200 to emit light.

Meanwhile, one of the first pad 142 and the second pad 160 may be electrically connected to the source/drain electrode 131 and 132 of the driving TFT 130, and the other of the first pad 142 and the second pad 160 may be electrically connected to the common voltage interconnection 150 through the common interconnection electrode 151.

Next, one of the n-type pad 220 and the p-type pad 230 may be prepared to provide a plurality of micro LEDs 200 provided on the side surface of the light-emitting structure 210 (see S200).

The micro LED 200 may include the light-emitting structure 210 in which the n-type semiconductor layer 211, the active layer 212, and the p-type semiconductor layer 213 are sequentially stacked, the n-type pad 220 electrically connecting the n-type semiconductor layer 211 to the first pads 141 and 142, and the p-type pad 230 electrically connecting the p-type semiconductor layer 213 to the second pad 160.

Unlike the general flip-chip type micro LED, in the present disclosure, one of the n-type pad 220 and the p-type pad 230 may be provided on the side surface of the light-emitting structure 210, and the other of the n-type pad 220 and the p-type pad 230 may be provided on the front or rear surface of the light-emitting structure. That is, the relative positions of the n-type pad 220 and the p-type pad 230 may not form a horizontal structure or a vertical structure, but form a structure in which the extending surface of the n-type pad 220 and the extending surface of the p-type pad 230 intersect each other in the present disclosure. For example, the n-type pad 220 and the p-type pad 230 form a right-angled structure.

One of the n-type pad 220 and the p-type pad 230 provided on the side surface of the light-emitting structure 210 may be provided at a higher position than the other of the n-type pad 220 and the p-type pad 230 provided on the front or rear surface of the light-emitting structure 210. Since the n-type pad 220 and the p-type pad 230 are provided at different heights, even when heat is applied, while pressing the micro LED against the driving substrate, during the operation of bonding the micro LED to the driving substrate, an electrical short-circuit due to a spreading phenomenon of the bonding material may be effectively suppressed.

Meanwhile, the operation (S200) of preparing a plurality of micro LEDs 200 may further include an operation of dicing a plurality of light-emitting units or light-emitting elements formed on a growth substrate and separating them into single micro LED chips. The operation of separating them into single micro LED chips may be performed by transferring a plurality of light- emitting units formed on the growth substrate onto a submount and then dicing them. Thereafter, an operation of removing the growth substrate by lifting off a sacrificial layer interposed between the growth substrate and the plurality of light-emitting units using a laser may further be included.

Finally, the plurality of micro LEDs 200 may be bonded to the driving substrate 100 such that one of the n-type pad 220 and the p-type pad 230 provided on the side surface of the light-emitting structure 210 is electrically connected to one of the first pad 142 and the second pad 160 and the other of the n-type pad and the p-type pad is electrically connected to the other of the first pad 142 and the second pad 160 (S300).

A plurality of micro LEDs 200 may be arranged on the driving substrate 100, and the n-type pad 220 and the p-type pad 230 of the micro LEDs 200 may be electrically connected to the first pad 142 or the second pad 160 arranged in a two-dimensional array form on the driving substrate 100, so that the plurality of micro LEDs may selectively emit light by the driving TFT.

The first pad 142 and the n-type pad 220, and the second pad 160 and the p-type pad 230 may form an electrical connection by disposing a bonding material, such as a solder ball, between the pads connected to each other or by forming a eutectic mixture.

Meanwhile, the operation (S100) of preparing the driving substrate may include an operation of forming the side contact portion 180 extending from the first pad 142 or the second pad 160 electrically connected to one of the n-type pad 220 and the p-type pad 230 provided on the side surface of the light-emitting structure 210 toward one of the n-type pad 220 and the p-type pad 230 provided on the side surface of the light-emitting structure 210.

The operation (S100) of preparing the driving substrate may further include the insulating layer 170 having the through-hole 171 provided to expose the first pad 142 or the second pad 160.

The operation of forming the side contact portion 180 may include an operation of forming a sacrificial layer 300 to expose one of the first pad 142 and the second pad 160 electrically connected to one of the n-type pad 220 and the p-type pad 230 provided on the side surface of the light-emitting structure 210; an operation of forming a conductive layer 400 on the sacrificial layer 300 and one of the exposed first pad 142 and the second pad 160; and an operation of removing the sacrificial layer 300.

The operation of forming the sacrificial layer 300 may be performed by forming the sacrificial layer 300 on the other of the first pad 142 and the second pad 160 electrically connected to the insulating layer 170 and the other of the n-type pad 220 and the p-type pad 230. Here, the sacrificial layer may not be formed on the insulating layer between the first pad 142 and the second pad 160. The sacrificial layer 300 may be, for example, a photoresist layer.

The side contact portion 180 may extend upward from the first pad 142 and the second pad 160, may be a pillar shape that protrudes further than an insulating layer 170 including a through-hole 171 provided to expose the first pad 142 and the second pad 160, or may be in a form embedded in the insulating layer 170.

The operation (S300) of bonding a plurality of micro LEDs to the driving substrate may include an operation of supplying energy so that one of the n-type pad 220 and the p-type pad 230 provided on the side surface of the light-emitting structure 210 and the side contact portion 180 form a eutectic mixture. Here, the energy supplied may be thermal energy, thermal compression energy that simultaneously applies heat and pressure, or light energy, such as a laser.

The operation (S300) of bonding a plurality of micro LEDs to the driving substrate may further include an operation of providing a plurality of micro LEDs 200 picked up by a transfer mechanism individually or collectively to the driving substrate 100 and bringing the side contact portion 180 into contact with one of the n-type pad 220 and the p-type pad 230 provided on the side surface of the light-emitting structure 210. When energy is supplied to the contacted side contact portion 180 and one of the n-type pad 220 and the p-type pad 230 provided on the side surface of the light-emitting structure 210, a eutectic mixture may be formed at a contact surface, thereby forming an electrical connection.

The side contact portion 180 and one of the n-type pad 220 and the p-type pad 230 provided on the side surface of the light-emitting structure 210 may each include a material that forms a eutectic mixture during the operation of supplying energy. That is, at least one metal among the materials forming the side contact portion 180 and at least one metal forming one of the n-type pad 220 and the p-type pad 230 provided on the side surface of the light-emitting structure 210 may form a eutectic mixture. Materials forming the eutectic mixture may be included in both the side contact portion 180 and one of the n-type pad 220 and the p-type pad 230 provided on the side surface of the light-emitting structure 210.

The side contact portion 180 and one of the n-type pad 220 and the p-type pad 230 provided on the side surface of the light-emitting structure 210 may include at least one of Pb, Sn, Au, Ge, Si, In, Ag, and Cu materials. In order to easily form the eutectic mixture by the supplied energy, the side contact portion 180 or one of the n-type pad 220 and the p-type pad 230 provided on the side surface of the light-emitting structure 210 may include tin (Sn), and the side contact portion 180 or the other of the n-type pad 220 and the p-type pad 230 provided on the side surface of the light-emitting structure 210 may include a metal forming a eutectic mixture with tin.

The operation (S300) of bonding a plurality of micro LEDs to the driving substrate may further include an operation of inserting at least a portion of the micro LED 200 into the through-hole corresponding to the first pad 142 or the second pad 160 electrically connected to the n-type pad 220 or the p-type pad 230 provided on the front or rear surface of the light-emitting structure 210. Here, the cross-sectional area of the through-hole may be larger than the cross-sectional area of the light-emitting structure 210 so that at least a portion of the micro LED 200 may be inserted.

The single-chip type micro LED 200 may be individually or collectively picked up by a transfer mechanism, transferred to the driving substrate 100, and then bonded to the driving substrate 100 so as to be mounted on the driving substrate 100. Here, the through-hole corresponding to the first pad 142 or the second pad 160 electrically connected to the n-type pad 220 or the p-type pad 230 provided on the front or rear surface of the light-emitting structure 210 may be used as a position determining unit of the micro LED to transfer the micro LED to the accurate position. In addition, by inserting and bonding at least a portion of the micro LED 200 into the through-hole, the micro LED 200 may be prevented from shifting away from the transferred position by thermal compression during the bonding process. Furthermore, when bonding the micro LED 200 and the driving substrate 100, at least a locally melted bonding material, etc. may be accommodated in the space between an inner wall of the driving hole and the side surface of the light-emitting structure 210, so that a spreading phenomenon of the bonding material may be suppressed, thereby preventing the n-type pad and the p-type pad from being electrically short-circuited.

Meanwhile, the micro LED 200 of the present disclosure may further include the electrically insulating passivation layer 240 provided on the side surfaces of the active layer 212 and the p-type semiconductor layer 213. The passivation layer 240 may also be provided on the upper (active layer side) side surface of the n-type semiconductor layer 211 in order to more stably insulate the n-type semiconductor layer 211 and the p-type semiconductor layer 213 from each other. By the passivation layer 240, the problem in which the n-type pad 220 or the p-type pad 230 formed on the side surface of the light-emitting structure 210 is misaligned or a partial region is locally melted during the operation of bonding the micro LED 200 and the driving substrate 100 so that a conductive material forming the n-type pad 220 or the p-type pad 230 is applied to the side surface of the active layer 212 to cause a short-circuit between the n-type semiconductor layer 211 and the p-type semiconductor layer 213 may be effectively suppressed.

According to the micro LED display device and the method for manufacturing a micro LED display device according to an exemplary and non-limiting embodiment of the present disclosure, since one of the n-type pad and the p-type pad is provided on the side surface of the light-emitting structure, there is no need to remove the active region to form the n-type pad in the flip-chip type micro LED, and thus, a decrease in the light-emitting efficiency due to the decrease in the active region may be suppressed.

In addition, since the n-type pad and the p-type pad are provided at different heights so as not to exist on the same horizontal plane and are electrically connected using the side contact portion, the occurrence of an electrical short due to contacting of bonding materials when bonding the micro LED and the driving substrate (or the backplane) may be effectively prevented.

In addition, stable bonding may be performed simply by forming a eutectic mixture between the n-type pad or the p-type pad and the side contact portion by supplying energy while the n-type pad or the p-type pad is in contact with the side contact portion.

Meanwhile, by inserting at least a portion of the micro LED into the through-hole of the insulating layer provided to expose the first pad and the second pad and bonding the same, the micro LED and the driving substrate may be precisely aligned, and a bonding material is prevented from spreading by the through-hole, thereby enabling stable bonding.

The meaning of ‘on ˜’ used in the above description includes a case of direct contacting and a case of not directly contacting but disposed to face an upper or lower portion, it is also possible to be positioned to face the entire upper or lower surface as well as partially face the upper or lower surface, and it is used to mean positionally away to face or directly contact the upper or lower surface. In addition, the terms ‘above,’ ‘below,’ ‘front,’ ‘rear,’ ‘upper,’ ‘lower,’ ‘top,’ ‘bottom,’ etc. used in the above description are defined based on the drawings for convenience, and the shape and position of each component are not limited by these terms.

Although the exemplary and non-limiting embodiments of the present disclosure have been illustrated and described above, the present disclosure is not limited to the above exemplary embodiments, and those skilled in the art will understand that various modifications and equivalent other exemplary embodiments are made without departing from the gist of the present disclosure claimed in the claims. Therefore, the technical protection scope of the present disclosure should be defined by the claims.

1. A micro LED display device comprising:
a driving substrate a first pad and a second pad connected to different potentials; and
a micro LED a light-emitting structure in which an n-type semiconductor layer, an active layer, and a p-type semiconductor layer are stacked, an n-type pad electrically connecting the n-type semiconductor layer to the first pad, and a p-type pad electrically connecting the p-type semiconductor layer to the second pad,
wherein one of the n-type pad and p-type pad is provided on a side surface of the light-emitting structure.

2. The micro LED display device of claim 1, wherein the other of the n-type pad and p-type pad is provided on a front or rear surface of the light-emitting structure.

3. The micro LED display device of claim 2, wherein one of the n-type pad and the p-type pad provided on the side surface of the light-emitting structure is provided at a higher position than the other of the n-type pad and the p-type pad provided on the front or rear surface of the light-emitting structure.

4. The micro LED display device of claim 1, wherein the driving substrate further a side contact portion extending from the first pad or the second pad electrically connected to one of the n-type pad and the p-type pad provided on the side surface of the light-emitting structure toward one of the n-type pad and the p-type pad provided on the side surface of the light-emitting structure.

5. The micro LED display device of claim 1, wherein
the driving substrate further:
a plurality of driving thin film transistors (TFTs) individually driving ON/OFF of the micro LEDs provided in plurality; and
a common voltage interconnection providing a common potential to the plurality of micro LEDs,
wherein one of the first pad and the second pad is electrically connected to a source/drain electrode of the driving TFT, and the other of the first pad and the second pad is electrically connected to the common voltage interconnection.

6. The micro LED display device of claim 1, wherein the micro LED further a passivation layer provided on side surfaces of the active layer and the p-type semiconductor layer.

7. The micro LED display device of claim 1, wherein, when the p-type pad is provided on the side surface of the light-emitting structure, the micro LED further a transparent p-type electrode provided on the p-type semiconductor layer.

8. The micro LED display device of claim 4, wherein one of the n-type pad and the p-type pad provided on the side surface of the light-emitting structure and a side contact portion each a material for forming a eutectic mixture during a bonding process.

9. The micro LED display device of claim 2, wherein the driving substrate further an insulating layer having a through-hole provided to expose the first pad and the second pad, and a cross-sectional area of the through-hole corresponding to the first pad or the second pad electrically connected to the n-type pad or the p-type pad provided on the front or rear surface of the light-emitting structure is larger than a cross-sectional area of the light-emitting structure.

10. The micro LED display device of claim 1, wherein an effective cross-sectional area of the micro LED is 100 μm² or less.

11. A method for manufacturing a micro LED display device, comprising:
preparing a driving substrate a first pad and a second pad connected to different potentials;
preparing a plurality of micro LEDs a light-emitting structure in which an n-type semiconductor layer, an active layer, and a p-type semiconductor layer are stacked, an n-type pad electrically connected to the n-type semiconductor layer, and a p-type pad electrically connected to the p-type semiconductor layer, one of the n-type pad and the p-type pad being provided on a side surface of the light-emitting structure; and
bonding the plurality of micro LEDs to the driving substrate so that one of the n-type pad and the p-type pad provided on the side surface of the light-emitting structure is electrically connected to one of the first pad and the second pad and the other of the n-type pad and the p-type pad is electrically connected to the other of the first pad and the second pad.

12. The method of claim 11, wherein the operation of preparing the driving substrate forming a side contact portion extending from the first pad or the second pad electrically connected to one of the n-type pad and the p-type pad provided on the side surface of the light-emitting structure toward one of the n-type pad and the p-type pad provided on the side surface of the light-emitting structure.

13. The method of claim 12, wherein the operation of bonding the plurality of micro LEDs to the driving substrate supplying energy so that one of the n-type pad and the p-type pad provided on the side surface of the light-emitting structure and the side contact portion form a eutectic mixture.

14. The method of claim 12, wherein
the driving substrate further an insulating layer having a through-hole provided to expose the first pad and the second pad, and
the operation of bonding the plurality of micro LEDs to the driving substrate
inserting at least a portion of the micro LED into the through-hole corresponding to the first pad or the second pad electrically connected to the n-type pad or the p-type pad provided on a front or rear surface of the light-emitting structure.

15. The method of claim 11, wherein the micro LED further a passivation layer provided on side surfaces of the active layer and the p-type semiconductor layer.
